(19) United States
(12) Patent Application Publication
(10) Pub. No.: US 2025/0210560 A1
(43) Pub. Date: Jun. 26, 2025

(54) SEMICONDUCTOR PACKAGE AND METHOD FOR MANUFACTURING THE SAME

(71) Applicant: Samsung Electronics Co., Ltd., Suwon-si (KR)

(72) Inventor: Ji-Han KO, Suwon-si (KR)

(73) Assignee: Samsung Electronics Co., Ltd., Suwon-si (KR)

(21) Appl. No.: 18/748,284

(22) Filed: Jun. 20, 2024

(30) Foreign Application Priority Data
Dec. 22, 2023 (KR) 10-2023-0190302

(51) Int. Cl. H01L 23/00

(52) U.S. Cl. CPC H01L 24/16; H01L 24/08; H01L 24/81; H01L 24/32; H01L 24/73; H01L 2224/08225; H01L 2224/16227; H01L 2224/32225; H01L 2224/73204; H01L 2224/81024; H01L 2224/81911; H01L 2924/1815

(57) ABSTRACT

The described technology relates generally to a semiconductor package and a method of manufacturing the same, the method of manufacturing a semiconductor package according to an example embodiment includes a method of manufacturing a semiconductor package including a package substrate including a main pad and a semiconductor chip including a chip pad, forming a coating layer containing a surface-active material on the main pad of the package substrate, forming a connection solder pattern on the chip pad of the semiconductor chip, forming a flux to surround the connection solder pattern, mounting the semiconductor chip on the package substrate so that the connection solder pattern and the main pad are in contact, and combining the flux with the surface-active material of the coating layer to form a flux structure, and including a cleaning step to remove at least a portion of the coating layer and the flux structure.

### CROSS-REFERENCE TO RELATED APPLICATION

This application claims priority to and the benefit of Korean Patent Application No. 10-2023-0190302 filed at the Korean Intellectual Property Office on Dec. 22, 2023, the entire contents of which are incorporated herein by reference.

### BACKGROUND

### 1. Field

The described technology relates generally to a semiconductor package and a method of manufacturing the same.

### 2. Description of the Related Art

The semiconductor industry is seeking to improve integration density so that more passive or active devices can be integrated within a given area.

Meanwhile, as the development of technology for refining the circuit line width of the entire semiconductor process gradually faces limitations, the semiconductor industry is making semiconductor packages that protect semiconductor chips with integrated circuits lighter, thinner, smaller, faster, and more functional, so there is a trend to complement the limitations of the semiconductor front-end process by developing semiconductor packages with high integration density.

On the other hand, semiconductor devices generally have electrical connection terminals such as solder balls or bumps to be electrically connected to other electronic devices or printed circuit boards.

As the connection terminals of semiconductor devices are required to have finer pitches, bonding defects are likely to occur during the solder ball attachment process, making it difficult to provide a reliable electrical connection between the semiconductor device and external devices.

### SUMMARY

Example embodiments disclose a semiconductor package with improved reliability and a method of manufacturing the same.

A method of manufacturing a semiconductor package according to an example embodiment includes forming a coating layer including a surface-active material on a main pad of a package substrate, applying a flux to a connection solder pattern included on a semiconductor chip and mounting the semiconductor chip on the package substrate so that the connection solder pattern and the main pad are in contact with each other, forming a flux structure by combining the flux with the surface-active material of the coating layer, and removing at least a portion of the coating layer and the flux structure.

A method of manufacturing a semiconductor package according to an example embodiment includes forming a coating layer including a surface-active material including a hydrophilic portion and a hydrophobic portion on a main pad of a package substrate, applying a flux including a hydrophobic material to a connection solder pattern on a chip pad of a semiconductor chip, mounting the semiconductor chip on the package substrate so that the connection solder pattern and the main pad penetrate the coating layer, wherein the flux combines with the hydrophobic portion of the surface-active material to form a flux structure having a micelle structure, and removing at least a portion of the coating layer and the flux structure.

A semiconductor package according to an example embodiment includes a package substrate including a main pad, a semiconductor chip mounted on the package substrate and including a chip pad, a connection bump positioned between the main pad and the chip pad, and a flux structure located on a side surface of the connection bump, the flux structure including a core of flux material and a surface-active material bonded to the core.

According to example embodiments, the reliability of a semiconductor package can be improved.

### BRIEF DESCRIPTION OF THE DRAWINGS

FIG. 1 and FIG. 2 are cross-sectional views showing an intermediate-stage manufacturing method of a semiconductor package according to an example embodiment.

FIG. 3 is a schematic diagram showing a surface-active material of a semiconductor package according to one example embodiment.

FIG. 4 to FIG. 8 are cross-sectional views showing an intermediate-stage manufacturing method of a semiconductor package according to an example embodiment.

FIG. 9 is a schematic diagram showing the flux structure of a semiconductor package according to one example embodiment.

FIG. 10 is a cross-sectional view showing an intermediate-stage manufacturing step of a semiconductor package according to an example embodiment.

FIG. 11 is an enlarged cross-sectional view of area A1 of FIG. 10.

FIG. 12 to FIG. 15 are cross-sectional views corresponding to area A1 of FIG. 10 illustrating semiconductor packages according to some example embodiments.

FIG. 16 is a cross-sectional view showing a semiconductor package of one example embodiment.

FIG. 17 is a cross-sectional view showing a semiconductor package according to some example embodiments.

### DETAILED DESCRIPTION

Hereinafter, with reference to the attached drawings, example embodiments will be described in detail so that those skilled in the art can easily implement the present invention. The present invention may be implemented in many different forms and is not limited to the example embodiments described herein.

In order to clearly explain the present invention in the drawings, parts not related to the description are omitted, and identical or similar components are given the same reference numerals throughout the specification.

In addition, the size and thickness of each component shown in the drawings are shown arbitrarily for convenience of explanation, so the present invention is not necessarily limited to that which is shown.

Throughout the specification, when a part is said to be “connected” to another part, this includes not only the case in which it is “directly connected” but also the case in which it is “indirectly connected” through another member. Additionally, when a part “includes” a certain component, this means that it may further include other components rather than excluding other components, unless specifically stated to the contrary.

Additionally, when a part of a layer, membrane, region, or plate is said to be “above” or “on” another part, this includes not only cases in which it is “directly above” another part, but also cases in which there is another part in between. Conversely, when a part is said to be “right on top” of another part, it means that there is no other part in between. In addition, being “above” or “on” a reference part means being located above or below the reference part, and does not necessarily mean being located “above” or “on” it in the direction opposite to gravity.

In addition, throughout the specification, when reference is made to “on a plane,” this means when the target portion is viewed from above, and when reference is made to “in cross-section,” this means when a cross-section of the target portion is cut vertically and viewed from the side.

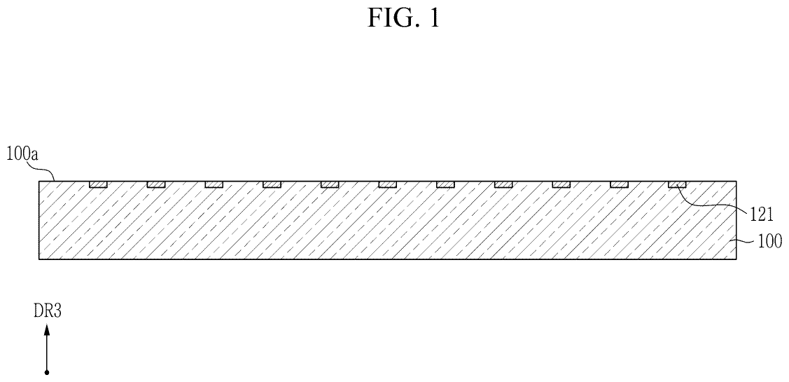

Hereinafter, a method of manufacturing a semiconductor package according to an example embodiment will be described with reference to FIGS. 1 to 16.

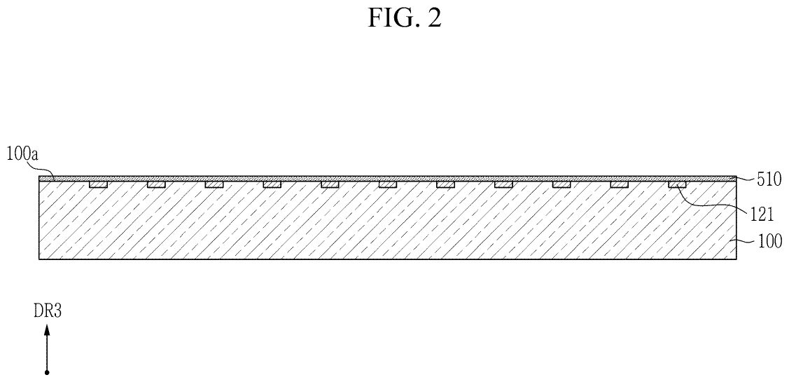

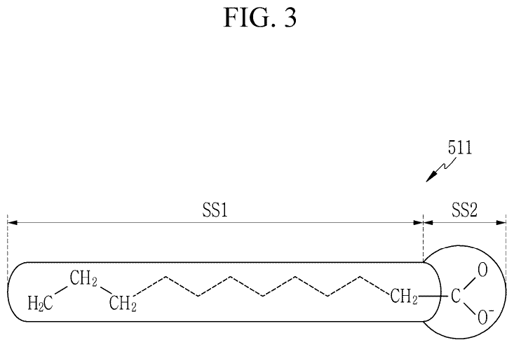

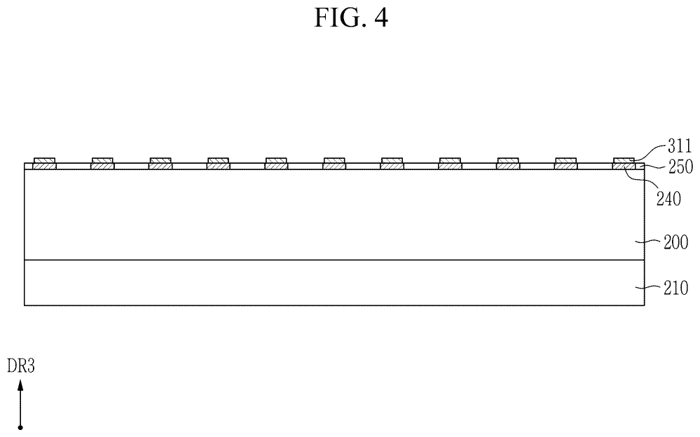

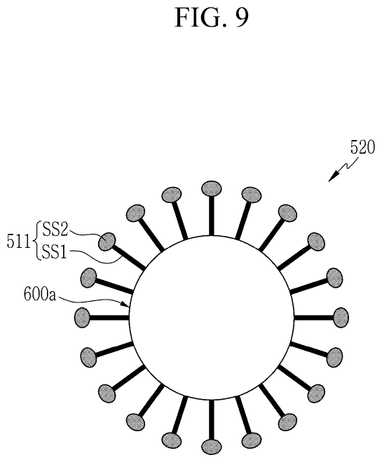

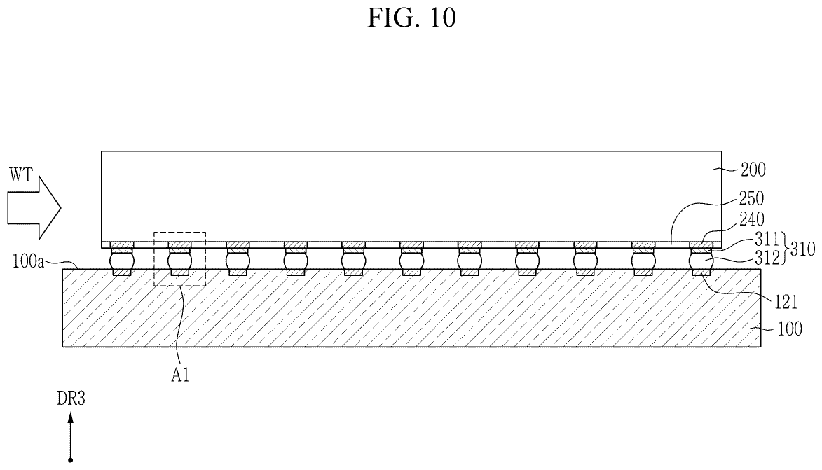

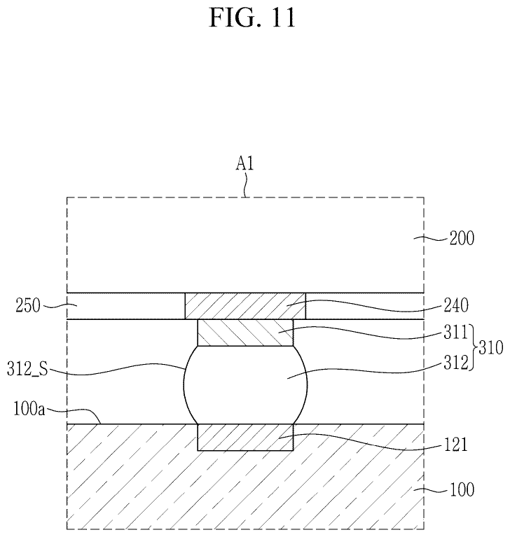

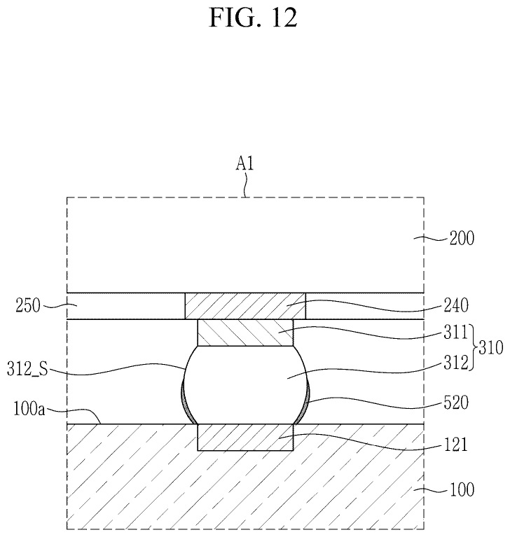

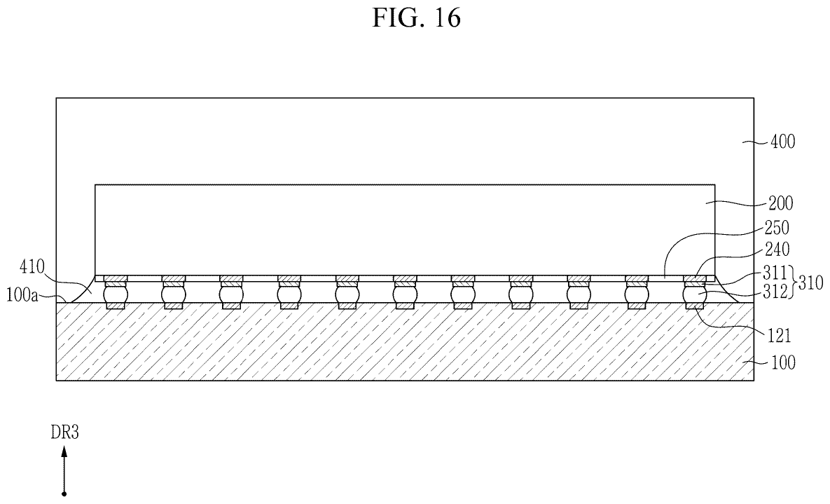

FIG. 1 and FIG. 2 are cross-sectional views showing an intermediate-stage manufacturing method of a semiconductor package according to an example embodiment. FIG. 3 is a schematic diagram showing a surface-active material of a semiconductor package according to one example embodiment. FIG. 4 to FIG. 8 are cross-sectional views showing an intermediate-stage manufacturing method of a semiconductor package according to an example embodiment. FIG. 9 is a schematic diagram showing the flux structure of a semiconductor package according to one example embodiment. FIG. 10 is a cross-sectional view showing an intermediate-stage manufacturing method of a semiconductor package according to an example embodiment. FIG. 11 is an enlarged cross-sectional view of area A1 of FIG. 10. FIG. 12 to FIG. 15 are cross-sectional views corresponding to area A1 of FIG. 10 illustrating semiconductor packages according to some example embodiments. FIG. 16 is a cross-sectional view showing a semiconductor package of one example embodiment.

Referring to FIG. 1, a package substrate 100 is prepared. The package substrate 100 may be a package substrate—for example, a printed circuit board (PCB) or a ceramic substrate.

When the package substrate 100 is a printed circuit board, the package substrate 100 may be made of at least one material selected from phenol resin, epoxy resin, and polyimide.

The package substrate 100 may have an upper surface 100a and a lower surface facing each other. The package substrate 100 may include integrated circuits. A semiconductor chip 200 (e.g. FIG. 4) may be mounted on the upper surface 100a of the package substrate 100. The package substrate 100 may be electrically connected to the semiconductor chip 200.

The package substrate 100 according to one example embodiment may include a main pad 121.

The main pad 121 may be located on top of the package substrate 100. The main pad 121 may penetrate at least a portion of the package substrate 100. The top surface of the main pad 121 may be located at substantially the same level as the top surface of the package substrate 100. That is, the upper surface of the main pad 121 may be aligned with the upper surface of the package substrate 100. However, it is not limited to this, and the main pad 121 may protrude from the upper surface 100a of the package substrate 100.

The main pads 121 may be provided in plurality, and the plurality of main pads 121 may be arranged to be spaced apart from each other in the horizontal direction on the top of the package substrate 100. The exposed upper surface of the main pad 121 may be connected to the connection bump 310, which will be explained later. The main pad 121 may include a conductive material. The main pad 121, for example, can include at least one of copper (Cu), nickel (Ni), chromium (Cr), aluminum (Al), silver (Ag), gold (Au), and iron (Fe).

In one example embodiment, at least some of the main pads 121 may be power pins or ground pins to which power voltage and/or ground voltage are applied, respectively. Additionally, the main pad 121 may be electrically connected to internal wiring and/or an internal via in the package substrate 100. Here, being electrically connected to a component includes direct connection or indirect connection through another conductive component.

Although not shown in the drawing, the package substrate 100 according to one example embodiment may further include a main wiring pattern and a main wiring insulating layer.

The main wiring pattern may be a wiring for applying a power voltage and/or ground voltage from the outside. That is, the main wiring pattern may be electrically connected to the main pad 121 so that a voltage applied from the outside can be applied to the main pad 121. Accordingly, voltage may be applied to the semiconductor chip 200 through the main pad 121 connected to the main wiring pattern. Additionally, the main wiring insulating layer may surround the main pad 121. For example, the main wiring insulating layer may be located on the upper surface 100a of the package substrate 100 and penetrated by the main pad 121. At this time, the top surface of the main wiring insulating layer may be located at substantially the same level as the top surface of the main pad 121. That is, the top surface of the main wiring insulating layer may be aligned with the top surface of the main pad 121. However, it is not limited to this, and the main pad 121 may protrude from the upper surface of the main wiring insulating layer. The main wiring insulating layer can prevent short-circuit between adjacent main pads 121. The main pad insulating layer may include at least one of a silicon-based insulating material such as silicon oxide or silicon nitride, a polymer such as polybenzoxazole (PBO), benzocyclobutene (BCB), or polyimide, and a nitride such as phosphosilicate glass (PSG) or borophosphosilicate glass (BPSG).

Referring to FIG. 2, a coating layer 510 may be formed on the upper surface 100a of the package substrate 100. The coating layer 510 may be located on the upper surface of the main pad 121. The coating layer 510 may cover the main pad 121. The coating layer 510 may be formed conformally on the upper surface 100a of the package substrate 100. However, it is not limited thereto, and for example, the coating layer 510 may be positioned on at least a portion of the package substrate 100. However, even in this case, the coating layer 510 may cover the upper surface of the main pad 121.

Referring further to FIG. 3, the coating layer 510 may include a surface-active material 511 and a coating material.

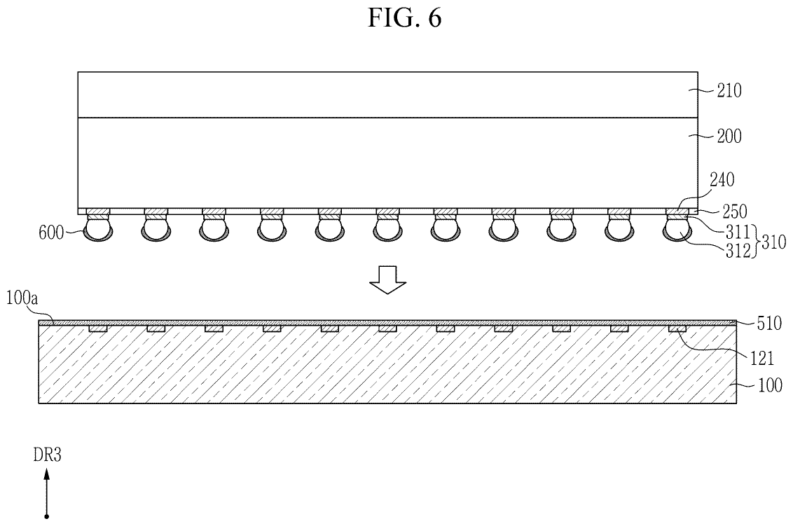

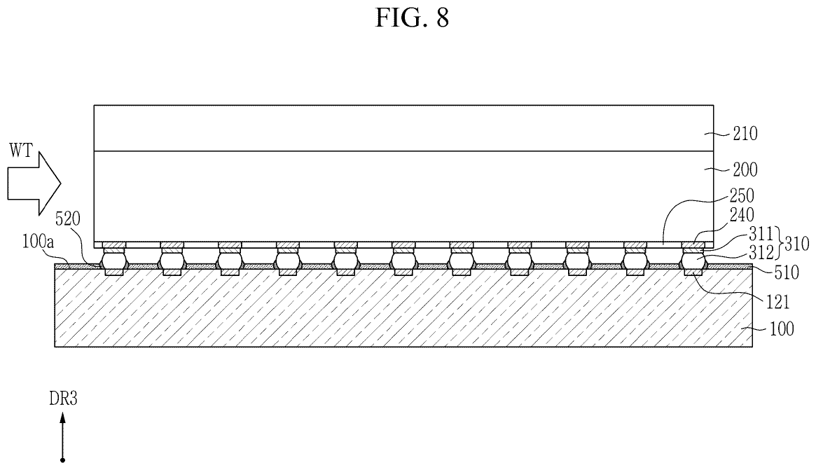

The surface-active material 511 may include a hydrophilic portion SS2 and a hydrophobic portion SS1. For example, the hydrophilic portion SS2 of the surface-active material 511 may include a carboxylic anion, and the hydrophobic portion SS1 of the surface-active material 511 may include a carbon chain. The hydrophobic part SS1 of the surface-active material 511 is the part that combines with a flux (600 in FIG. 6), which will be explained later, and the hydrophilic part SS2 forms the surface of the flux structure (520 in FIG. 8), which will be explained later. That is, the surface-active material 511 may be an amphipathic material that has both hydrophilic and lipophilic properties. As an example, the surfactant material 511 may be a surfactant or surface-active agent. Additionally, the coating material may include a water-soluble polymer. For example, the coating material may include a vinyl-based polymer containing hydroxy groups (e.g., polyvinyl alcohol).

In FIG. 3, the surface-active material 511 is shown as including a carboxylic anion and a carbon chain, but it is not limited thereto, and the materials constituting the surface-active material 511 can be varied to include hydrophilic and hydrophobic properties.

In one example embodiment, the surface-active material 511 may comprise about 5 wt % to about 50 wt % of the total weight of the coating layer 510, and the coating material may comprise about 50 wt % to about 95 wt % of the coating layer 510. Within this range, the coating layer 510 can be easily formed on the package substrate 100, and the flux 600, which will be described later, can easily combine with the surface-active material 511. That is, if the surface-active material 511 is less than 5 wt % with respect to the coating layer 510, the flux 600, which will be described later, may not sufficiently bind to the surface-active material 511. Also, if the surface-active material 511 is more than 50 wt % for the coating layer 510, a problem may arise where the coating layer 510 is not formed conformally on the upper surface 100a of the package substrate 100.

Referring to FIG. 4, a semiconductor chip 200 may be prepared on a carrier substrate 210, and a connection pillar 311 may be formed on the semiconductor chip 200.

The semiconductor chip 200 may include a three-dimensional integrated circuit (3D IC) structure. Additionally, in one example embodiment, the semiconductor chip 200 may include a system on chip (SOC). For example, the semiconductor chip 200 may include at least one of a central processing unit (CPU), a graphics processing unit (GPU), memory, a controller, a codec, a sensor, and a communication chip. However, it is not limited to this, and the semiconductor chip 200 may include a single chip such as DRAM or multiple chips such as high bandwidth memory HBM.

The semiconductor chip 200 of the semiconductor package according to one example embodiment may include a chip pad insulating layer 250 and a chip pad 240.

The chip pad insulating layer 250 may be located on one surface of the semiconductor chip 200. For example, the chip pad insulating layer 250 may be located below the semiconductor chip 200. The chip pad insulating layer 250 can prevent the chip pads 240 from short-circuiting each other. The chip pad insulating layer 250 may include at least one of a silicon-based insulator such as silicon oxide or silicon nitride, a polymer such as PBO, BCB, or polyimide, and a nitride such as PSG or BPSG.

The chip pad 240 may be located on one surface of the semiconductor chip 200. For example, the chip pad 240 may be positioned under the semiconductor chip 200. The chip pad 240 may penetrate the chip pad insulating layer 250. The chip pad 240 may be electrically connected to integrated circuits through interconnection structures within the semiconductor chip 200. A plurality of chip pads 240 may be provided, and the plurality of chip pads 240 may be positioned to be spaced apart from each other in the horizontal direction. The chip pad 240 may include a conductive material. In at least one example embodiment, the chip pad 240 includes at least one of copper (Cu), nickel (Ni), chromium (Cr), aluminum (Al), silver (Ag), gold (Au), and/or iron (Fe).

In one example embodiment, although not shown in the drawings, the semiconductor chip 200 may further include a semiconductor substrate, integrated circuits, and a wiring layer. Integrated circuits and wiring layers may be electrically connected to the chip pad 240. Accordingly, the signal transmitted to the chip pad 240 can be applied to the integrated circuits through the wiring layer, and the integrated circuits can operate according to the applied signal.

In one example embodiment, the connection pillar 311 may be formed on the semiconductor chip 200. Specifically, the connection pillar 311 may be formed on the chip pad 240 of the semiconductor chip 200. That is, the connection pillar 311 may be formed to overlap the chip pad 240 in a third direction DR3. The connection pillar 311 may be physically and electrically connected to the chip pad 240. The connection pillar 311 may be formed at a position corresponding to the main pad 121 of the package substrate 100.

In one example embodiment, the connection pillar 311 may be provided on one surface of the chip pad 240. For example, the connection pillar 311 may be formed on the upper surface of the chip pad 240. The connection pillar 311 may overlap the chip pad 240 in the third direction DR3. The connection pillar 311 may be electrically connected to the chip pad 240. The connection pillar 311 may be located between the chip pad 240 and the connection solder pattern 312, which will be described later.

The connection pillar 311 may have a cylindrical shape in a plan view, but is not limited thereto. For example, the connection pillar 311 may have a shape such as a polygon or an ellipse. In one example embodiment, a plurality of connection pillars 311 are provided, and each of the plurality of connection pillars 311 may be formed to have substantially the same thickness. The connection pillar 311 may include a conductive material. The connection pillar 311 may include, for example, tin (Sn), silver (Ag), copper (Cu), tungsten (W), and/or alloys thereof.

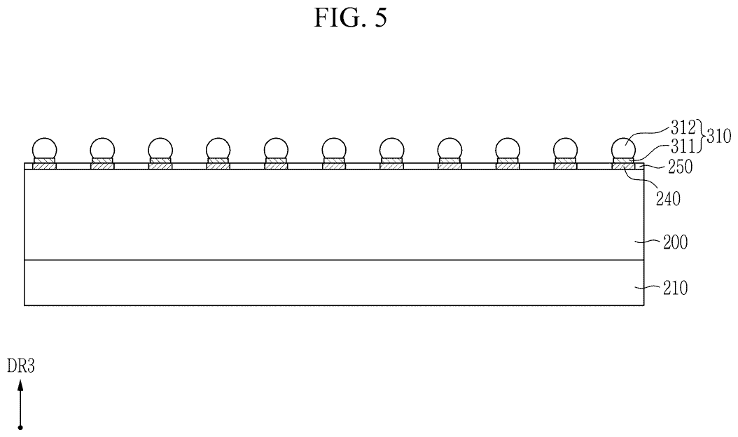

Referring to FIG. 5, a connection solder pattern 312 may be formed on the upper surface of the connection pillar 311. The connection solder pattern 312 may include a conductive material. The connection solder pattern 312 may include, for example, tin (Sn), silver (Ag), copper (Cu), manganese (Mn), lead (Pb), and/or alloys thereof. The connection solder pattern 312 may include, for example, solder balls and/or solder bumps. Accordingly, the connection bump 310 can be formed including the connection pillar 311 and the connection solder pattern 312.

Referring to FIG. 6, the flux 600 is formed to surround at least a portion of the connection solder pattern 312 located on one surface of the semiconductor chip 200, and the connection solder pattern 312 is formed on the top of the package substrate 100 such that the semiconductor chip 200 may be positioned to face the surface 100a.

First, the flux 600 may be formed to surround at least a portion of the connection solder pattern 312. The flux 600 may be formed conformally on the side and bottom surfaces of the connection solder pattern 312. The flux 600 may be positioned on the side and bottom surfaces of the connection solder pattern 312. The flux 600 may surround at least a portion of the side surface of the connection solder pattern 312. Accordingly, the surface of the connection solder pattern 312 may be blocked from the outside by the flux 600. In other words, the flux 600 can prevent the connection solder pattern 312 from being exposed to the outside and being oxidized. The flux 600 may include a material with flowability. The flux 600 may include a material having a hydrophobic functional group. Additionally, the flux 600 may include an acidic material.

Next, the semiconductor chip 200 may be positioned so that the connection solder pattern 312 faces the upper surface 100a of the package substrate 100. For example, the semiconductor chip 200 may be positioned so that the connection solder pattern 312 faces the upper surface of the main pad 121. Accordingly, the connection bump 310 may overlap the main pad 121 in the third direction DR3.

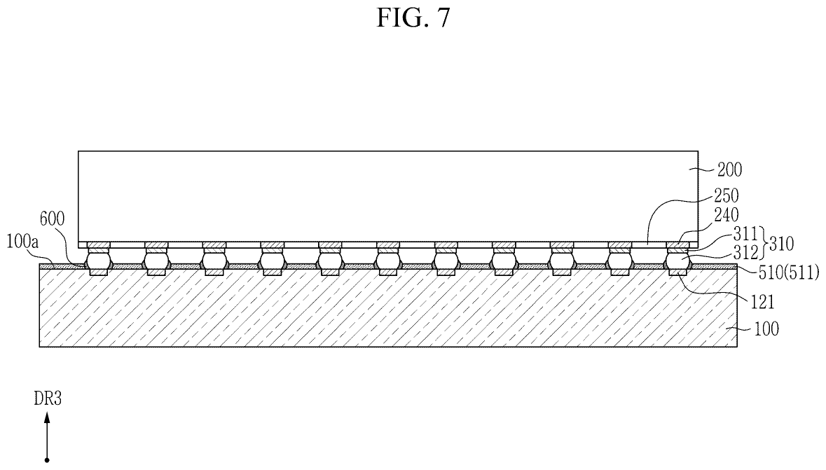

Referring to FIG. 7, the semiconductor chip 200 and the package substrate 100 can be bonded.

Specifically, the connection solder pattern 312 of the semiconductor chip 200 may contact the coating layer 510 located on the upper surface of the main pad 121. At this time, a predetermined pressure and heat may be provided between the semiconductor chip 200 and the package substrate 100, and the main pad 121 may be formed by the flux 600 surrounding at least a portion of the connection solder pattern 312, and a portion of the coating layer 510 located on the upper surface may be removed. For example, the flux 600 may contain an acidic material, and when the flux 600 and the coating layer 500 come into contact, the coating layer 500 may be removed by the flux 600.

Accordingly, the connection solder pattern 312 and the main pad 121 can be in contact, and the connection solder pattern 312 and the main pad 121 may be bonded. Accordingly, the connection solder pattern 312 may overlap the main pad 121 in the third direction DR3. Accordingly, the chip pad 240 and the main pad 121 may be electrically connected by the connection solder pattern 312 and the connection pillar 311. That is, the semiconductor chip 200 may be electrically connected to the package substrate 100.

In one example embodiment, as the semiconductor chip 200 and the package substrate 100 are bonded, the connection bump 310 may be located between the chip pad 240 and the main pad 121. For example, the connection pillar 311 may be located between the chip pad 240 and the connection solder pattern 312, and the connection solder pattern 312 may be located between the connection pillar 311 and the main pad 121.

Additionally, the flux 600 may be located on the side surface of the connection solder pattern 312 and may not be located on the lower surface of the connection solder pattern 312. This is because the flux 600, which includes a substance with fluidity, may be pushed to both sides of the connection solder pattern 312 as the connection solder pattern 312 and the main pad 121 are bonded, with some of the flux 600 located above the underside of the connection solder pattern 312. For example, the flux 600 may surround at least a portion of the connection solder pattern 312. The flux 600 may not be in contact with the main pad 121, but is not limited to this. Additionally, in FIG. 7, the flux 600 is shown surrounding at least a portion of the connection solder pattern 312, but it is not limited thereto. For example, the flux 600 may be located on the upper surface of the coating layer 510 located between the connecting solder patterns 312.

Referring to FIGS. 8 to 15, a cleaning step may be performed to remove the coating layer 510 and the flux structure 520 located between the semiconductor chip 200 and the package substrate 100.

First, referring to FIGS. 8 and 9, a cleaning material WT may be provided between the package substrate 100 and the semiconductor chip 200.

The cleaning material WT may flow between the package substrate 100 and the semiconductor chip 200 from one side surface of the semiconductor chip 200. The cleaning material (WT) may include a material with flowability. The cleaning material WT may include a material capable of dissolving the coating layer 510 and the flux structure 520. For example, the cleaning material (WT) may be water (H₂O).

At this time, at least a portion of the flux 600 located on the side surface of the connection solder pattern 312 and the surface-active material 511 of the coating layer 510 located on the upper surface 100a of the package substrate 100 may react to form the flux structure 520. For example, as shown in FIG. 9, the flux structure 520 may have a micelle structure having the flux material 600a as a core. That is, the flux structure 520 may include a core including the flux material 600a and the surface-active material 511 surrounding the flux material 600a. At this time, the hydrophobic portion SS1 of the surface-active material 511 may be combined with the flux material 600a, and the hydrophilic portion SS2 of the surface-active material 511 may form the surface of the flux structure 520. Even if the flux 600 has lipophilicity due to the flux structure 520 having a micelle structure, the surface of the flux structure 520 can have hydrophilicity, so the flux structure 520 can be smoothly dissolved in water.

In one example embodiment, the flux structure 520 may be located on the side surface of the connecting solder pattern 312. For example, the flux structure 520 may surround at least a portion of the connecting solder pattern 312. The flux structure 520 may not be in contact with the main pad 121, but is not limited to this. Additionally, in FIG. 8, the flux structure 520 is shown surrounding at least a portion of the connection solder pattern 312, but it is not limited thereto. For example, the flux structure 520 may be located on the upper surface of the coating layer 510 located between the connecting solder patterns 312.

Next, referring to FIGS. 10 to 15, at least a portion of the coating layer 510 and the flux structure 520 located between the semiconductor chip 200 and the package substrate 100 are removed using a cleaning material WT.

In one example embodiment, as shown in FIGS. 10 and 11, the coating layer 510 and the flux structure 520 located between the semiconductor chip 200 and the package substrate 100 can be completely removed.

Accordingly, the upper surface 100a of the package substrate 100 and the side surface 312_S of the connection solder pattern 312 may be exposed. The semiconductor package according to one example embodiment forms a coating layer 510 on the upper surface 100a of the package substrate 100, so that the flux 600 is applied to the coating layer during the bonding process between the semiconductor chip 200 and the package substrate 100. By combining the surface-active material 511 with the coating layer 510, a flux structure 520 having a micelle structure can be formed, and the flux structure 520 can be easily removed in the subsequent cleaning step.

However, it is not limited to this, and depending on the example embodiment, the flux structure 520 may remain on the surface of the connection solder pattern 312.

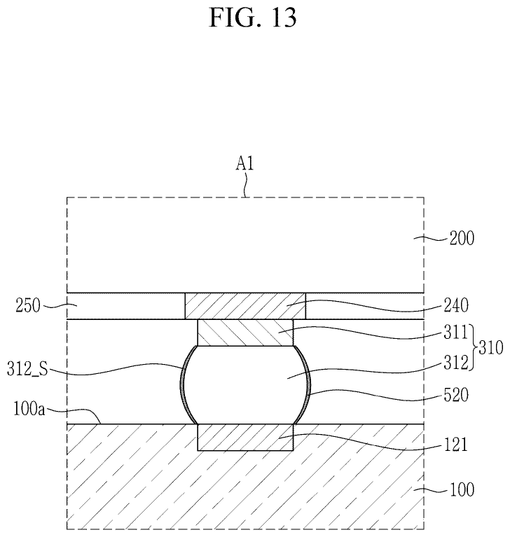

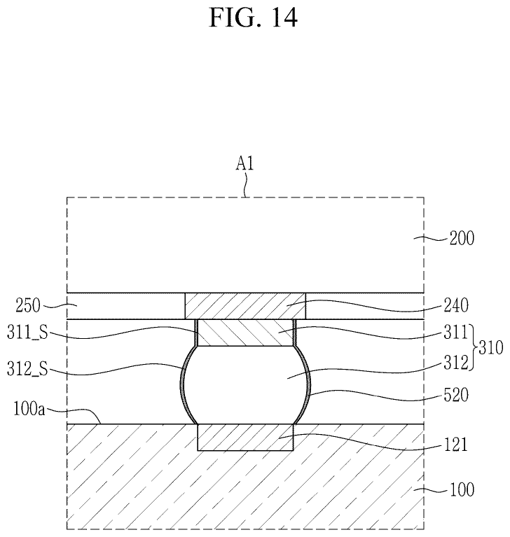

For example, as shown in FIG. 12, the flux structure 520 may be positioned on at least a portion of the side surface 312_S of the connecting solder pattern 312. At this time, the flux structure 520 may be in contact with the upper surface 100a of the package substrate 100, but is not limited to this, and the flux structure 520 may be in contact with the upper surface 100a of the package substrate 100 and it may be located spaced apart in the third direction DR3. Additionally, the flux structure 520 may not extend along the upper surface 100a of the package substrate 100. As another example, as shown in FIG. 13, the flux structure 520 may surround the entire side surface 312_S of the connection solder pattern 312. Even in this case, the flux structure 520 may not extend along the upper surface 100a of the package substrate 100. As another example, as shown in FIG. 14, the flux structure 520 may be located on the side surface 312_S of the connection solder pattern 312 and the side surfaces of the plurality of connection pillars 311. Even in this case, the flux structure 520 may not extend along the upper surface 100a of the package substrate 100. Even when the semiconductor package according to the example embodiment of FIGS. 12 to 14 includes a flux structure 520, the surface of the flux structure 520 is made up of the hydrophilic part SS2 of the surface-active substance 511, which may reduce its reactivity with the underfill film 410 to be described later.

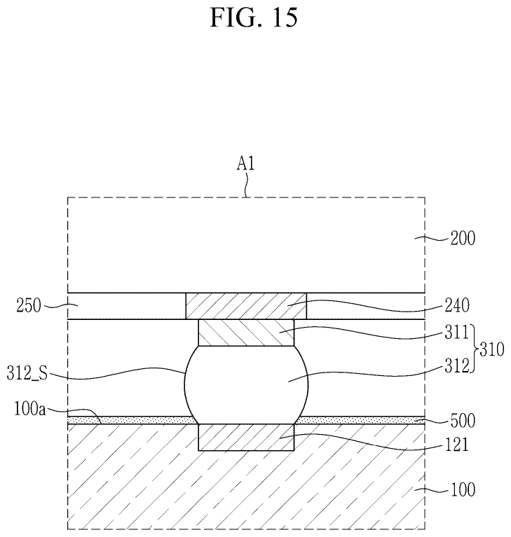

In one example embodiment, it is stated that the coating layer 510 is completely removed in the cleaning step of removing the coating layer 510 and the flux structure 520, but it is not limited thereto. For example, as shown in FIG. 15, a portion of the coating layer 510 may remain on the upper surface 100a of the package substrate 100. In this case, the coating layer 510 may not be located between the connection solder pattern 312 and the main pad 121.

Referring to FIG. 16, an underfill layer 410 can be formed in the space between the semiconductor chip 200 and the package substrate 100, and a molding film 400 can be formed to cover the semiconductor chip 200.

First, an underfill layer 410 may be formed in the space between the semiconductor chip 200 and the package substrate 100. The underfill layer 410 may flow from one side surface of the semiconductor chip 200 between the package substrate 100 and the semiconductor chip 200. The underfill layer 410 may include a material with flowability, and may cover the connection bump 310 while flowing between the package substrate 100 and the semiconductor chip 200. Accordingly, the connection bump 310 can be sealed by the underfill layer 410.

Subsequently, the molding film 400 may be formed to cover the semiconductor chip 200. The molding process using the molding film 400 may include a compression molding or transfer molding process. The process of forming a molding film 400 may include forming a molding material to cover the semiconductor chip 200, and then performing chemical mechanical polishing CMP on the upper surface of the molding film 400 to flatten it. Accordingly, a semiconductor package according to one example embodiment can be formed.

A method of manufacturing a semiconductor package according to an example embodiment includes bonding the semiconductor chip 200 and the package substrate 100 by forming the coating layer 510 on the upper surface 100a of the package substrate 100, and performing a subsequent cleaning step, the flux 600 may combine with the surface-active material 511 of the coating layer 510 to form the flux structure 520 having a micelle structure. Accordingly, the flux structure 520 can be easily removed. Therefore, when the underfill layer 410 is formed between the semiconductor chip 200 and the package substrate 100, the underfill layer 410 can easily seal the connection bump 310, and the reliability of the semiconductor package is improved.

In addition, even when the semiconductor package according to the example embodiment of FIGS. 12 to 14 includes the flux structure 520, since the surface of the flux structure 520 is made of the hydrophilic portion SS2 of the surface-active material 511, reactivity with the underfill layer 410 may be reduced. Accordingly, the underfill layer 410 can easily cover the flux structure 520, and the connection bump 310 can be easily sealed by the underfill layer 410.

Hereinafter, the structure of the semiconductor package according to the semiconductor package manufacturing method according to an example embodiment will be described with reference to FIG. 16.

FIG. 16 is a cross-sectional view showing a semiconductor package of one example embodiment.

Referring to FIG. 16, a semiconductor package according to an example embodiment may include a package substrate 100, a semiconductor chip 200, and a connection bump 310.

The package substrate 100 may be a package substrate—for example, a printed circuit board (PCB) or a ceramic substrate. When the package substrate 100 is a printed circuit board, the package substrate 100 may be made of at least one material selected from phenol resin, epoxy resin, and polyimide. The package substrate 100 may have an upper surface 100a and a lower surface facing each other. The package substrate 100 may include integrated circuits.

The semiconductor chip 200 may be mounted on the upper surface 100a of the package substrate 100. The package substrate 100 may be electrically connected to the semiconductor chip 200. A package substrate 100 according to one example embodiment may include a main pad 121.

Since the description of the main pad 121 is substantially the same as the description of the main pad 121 in the example embodiment of FIG. 1, it will be omitted.

In some example embodiments, a coating layer (500 in FIG. 15) may be further positioned on the upper surface 100a of the package substrate 100. For example, as shown in the example embodiment of FIG. 15, the coating layer (500 in FIG. 15) may be located on the upper surface 100a of the package substrate 100. The coating layer (500 in FIG. 15) may be located between the package substrate 100 and the underfill layer 410. The coating layer (500 in FIG. 15) may not be located between the main pad 121 and the connection bump 310. The coating layer (500 in FIG. 15) may include a surface-active material 511 and a coating material, and the surface-active material 511 may include a hydrophilic portion SS2 and a hydrophobic portion SS1. For example, the hydrophilic portion SS2 of the surface-active material 511 may include a carboxylic anion, and the hydrophobic portion SS1 of the surface-active material 511 may include a carbon chain. The surface-active material 511 may be an amphipathic material that has both hydrophilic and lipophilic properties. As an example, the surfactant material 511 may be a surfactant or a surface-active agent. Additionally, the coating material may include a water-soluble polymer. For example, the coating material may include a vinyl-based polymer containing hydroxy groups (e.g., polyvinyl alcohol).

Although not shown in the drawing, a package substrate 100 according to one example embodiment may further include a main wiring pattern and a main wiring insulating layer.

The main wiring pattern may be a wiring for applying a power voltage and/or ground voltage from the outside. That is, the main wiring pattern is electrically connected to the main pad 121 so that voltage applied from the outside can be applied to the main pad 121. Accordingly, voltage may be applied to the semiconductor chip 200 through the main pad 121 connected to the main wiring pattern. Additionally, the main wiring insulating layer may surround the main pad 121. For example, the main wiring insulating layer may be located on the upper surface 100a of the package substrate 100 and penetrated by the main pad 121. At this time, the top surface of the main wiring insulating layer may be located at substantially the same level as the top surface of the main pad 121. That is, the top surface of the main wiring insulating layer may be aligned with the top surface of the main pad 121. However, it is not limited to this, and the main pad 121 may protrude from the upper surface of the main wiring insulating layer. The main wiring insulating layer can prevent short-circuits between adjacent main pads 121. The main pad insulating layer may include at least one of a silicon-based insulating material such as silicon oxide or silicon nitride, a polymer such as PBO, BCB, or polyimide, and a nitride such as PSG or BPSG.

A semiconductor chip 200 may be mounted on the package substrate 100 according to one example embodiment.

The semiconductor chip 200 may include a three-dimensional integrated circuit (3D IC) structure. Additionally, in one example embodiment, the semiconductor chip 200 may include a system on chip (SOC). For example, the semiconductor chip 200 may include at least one of a central processing unit (CPU), a graphics processing unit (GPU), memory, a controller, a codec, a sensor, and a communication chip. However, it is not limited to this, and the semiconductor chip 200 may include a single chip such as DRAM or multiple chips such as high-bandwidth memory HBM.

The semiconductor chip 200 of the semiconductor package according to one example embodiment may include a chip pad insulating layer 250 and a chip pad 240.

The chip pad insulating layer 250 may be located below the semiconductor chip 200. The chip pad insulating layer 250 can prevent the chip pads 240 from short-circuiting each other. The chip pad insulating layer 250 may include at least one of a silicon-based insulating material such as silicon oxide or silicon nitride, a polymer such as PBO, BCB, or polyimide, and a nitride such as PSG or BPSG.

The chip pad 240 may be provided on the lower part of the semiconductor chip 200. The chip pad 240 may be embedded in the lower surface of the semiconductor chip 200. The chip pad 240 may be electrically connected to integrated circuits through interconnection structures within the semiconductor chip 200. The chip pads 240 may be positioned spaced apart from each other.

In one example embodiment, the chip pad 240 may be physically and electrically connected to the connection pillar 311. The chip pad 240 may overlap the connection pillar 311 in the third direction DR3. The chip pad 240 may include a conductive material. For example, the chip pad 240 includes at least one of copper (Cu), nickel (Ni), chromium (Cr), aluminum (Al), silver (Ag), gold (Au), and/or iron (Fe). In some example embodiments, although not shown in the drawings, the semiconductor chip 200 may further include a semiconductor substrate, integrated circuits, and a wiring layer. Integrated circuits and wiring layers may be electrically connected to the chip pad 240. Accordingly, the signal transmitted to the chip pad 240 can be applied to the integrated circuits through the wiring layer, and the integrated circuits can operate according to the applied signal.

A connection bump 310 and an underfill layer 410 may be included between a semiconductor chip 200 and a package substrate 100 according to an example embodiment.

The connection bump 310 may be positioned between the semiconductor chip 200 and the package substrate 100. That is, the connection bump 310 is located between the main pad 121 and the chip pad 240, and may be electrically connected to the main pad 121 and the chip pad 240. Each of the connection bumps 310 may overlap the main pad 121 in the third direction DR3. Accordingly, the semiconductor chip 200 may be electrically connected to the package substrate 100 through the connection bump 310. In one example embodiment, a plurality of connection bumps 310 are provided, and the plurality of connection bumps 310 may be arranged to be spaced apart from each other.

The connection bump 310 may include a connection pillar 311 and a connection solder pattern 312.

The connection pillar 311 may be provided on the lower surface of the chip pad 240. The connection pillar 311 may overlap the chip pad 240 in the third direction DR3. The connection pillar 311 may be located between the chip pad 240 and the connection solder pattern 312. The connection pillar 311 may be electrically connected to the chip pad 240 and the connection solder pattern 312.

The connection pillar 311 may have a cylindrical shape. For example, the connection pillar 311 may have a circular shape on a plane, but is not limited thereto.

The connection pillar 311 may include a conductive material. The connection pillar 311 may include, for example, tin (Sn), silver (Ag), copper (Cu), tungsten (W), and/or alloys thereof.

The connection solder pattern 312 may be provided under the lower surface of the connection pillar 311. The connection solder pattern 312 may be located between the connection pillar 311 and the main pad 121. The connection solder pattern 312 may be electrically connected to the connection pillar 311 and the main pad 121. The connection solder pattern 312 may include a conductive material. The connection solder pattern 312 may include, for example, tin (Sn), silver (Ag), copper (Cu), manganese (Mn), lead (Pb), and/or alloys thereof. The connection solder pattern 312 may include, for example, solder balls and solder bumps.

The underfill layer 410 may be provided in the gap area between the package substrate 100 and the semiconductor chip 200. The underfill layer 410 may cover the side surface of the connection bump 310. The underfill layer 410 may seal the connection bump 310. Additionally, the underfill layer 410 may extend along the side surface of the semiconductor chip 200, but is not limited thereto.

In one example embodiment, the underfill layer 410 may contact the side surface of the connection bump 310. For example, the underfill layer 410 may contact the side surface of the connection pillar 311 and the side surface of the connection solder pattern 312, but is not limited thereto. For example, as shown in FIG. 12, the flux structure 520 may be positioned on at least a portion of the side surface 312_S of the connecting solder pattern 312. At this time, the flux structure 520 may be in contact with the upper surface 100a of the package substrate 100, but is not limited to this, and the flux structure 520 may be spaced apart from the top surface 100a of the package substrate 100 in the third direction DR3. Additionally, the flux structure 520 may not extend along the upper surface 100a of the package substrate 100. As another example, as shown in FIG. 13, the flux structure 520 may surround the entire side surface 312_S of the connection solder pattern 312. Even in this case, the flux structure 520 may not extend along the upper surface 100a of the package substrate 100. As another example, as shown in FIG. 14, the flux structure 520 may be located on the side surface 312_S of the connection solder pattern 312 and the side surfaces of the plurality of connection pillars 311. Even in this case, the flux structure 520 may not extend along the upper surface 100a of the package substrate 100. Even when the semiconductor package according to the example embodiment of FIGS. 12 to 14 includes the flux structure 520, since the surface of the flux structure 520 is made of the hydrophilic portion SS2 of the surface-active material 511, reactivity with the underfill layer 410, which will be explained later, may decrease.

In one example embodiment, the underfill layer 410 may include a material with flowability. For example, the underfill layer 410 may include an insulating polymer such as an epoxy-based polymer. The underfill layer 410 may be formed by a capillary flow process after the semiconductor chip 200 is mounted on the package substrate 100.

The semiconductor package according to one example embodiment may further include a molding film 400.

The molding film 400 may be positioned on the top surface of the semiconductor chip 200 and the top surface of the package substrate 100. The molding film 400 may cover the semiconductor chip 200. The molding film 400 may include an insulating polymer such as, for example, an epoxy-based molding compound. However, it is not limited to this, and the molding film 400 may further extend between the package substrate 100 and the semiconductor chip 200.

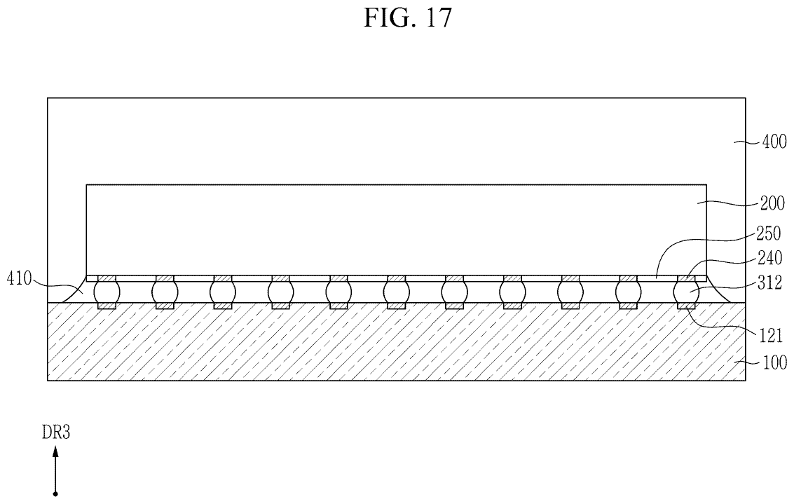

Hereinafter, semiconductor packages according to some example embodiments will be described with reference to FIG. 17.

FIG. 17 is a cross-sectional view showing a semiconductor package according to some example embodiments.

FIG. 17 shows various modifications of the semiconductor device according to the example embodiment shown in FIG. 16. Since the example embodiment shown in FIG. 17 has many of the same parts as the example embodiment shown in FIG. 16, description thereof will be omitted and the differences will be mainly explained. In addition, the same reference numerals are used for the same components as those in the previous example embodiment. The example embodiment shown in FIG. 17 may be slightly different from the previous example embodiment in that it does not include a connection pillar.

Referring to FIG. 17, a semiconductor package according to some example embodiments may include a package substrate 100, a semiconductor chip 200, and a connection solder pattern 312.

In some example embodiments, the connecting solder pattern 312 may be located between the chip pad 240 and the main pad 121. A connection solder pattern 312 may be provided on the lower surface of the chip pad 240. The connection solder pattern 312 may be in contact with the chip pad 240 and the main pad 121, and may be electrically connected. The connection solder pattern 312 may include, for example, solder balls and solder bumps.

In some example embodiments, the underfill layer 410 may contact the side surface of the connection solder pattern 312. For example, the underfill layer 410 may contact the side surface of the connection solder pattern 312, but is not limited thereto. For example, as shown in FIG. 12, the flux structure 520 may be positioned on at least a portion of the side surface 312_S of the connecting solder pattern 312.

Semiconductor packages according to some example embodiments may also be formed according to the example embodiments of FIGS. 1 to 16. Therefore, in the case of the semiconductor package manufacturing method according to some example embodiments, the semiconductor chip 200 and the package substrate 100 are bonded by forming a coating layer 510 on the upper surface 100a of the package substrate 100, and in the subsequent cleaning step, the flux 600 may combine with the surface-active material 511 of the coating layer 510 to form a flux structure 520 having a micelle structure. Accordingly, the flux structure 520 can be easily removed.

Therefore, when the underfill layer 410 is formed between the semiconductor chip 200 and the package substrate 100, the underfill layer 410 can easily seal the connection bump 310, and the reliability of the semiconductor package is improved.

Where the term “same” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

Where the term, “about” or “substantially” is used in this specification in connection with a numerical value, it is intended that the associated numerical value includes a manufacturing or operational tolerance (e.g., ±10%) around the stated numerical value. Moreover, where the word “generally” or “substantially” is used in connection with geometric shapes, it is intended that precision of the geometric shape is not required but that latitude for the shape is within the scope of the disclosure. Furthermore, regardless of whether numerical values or shapes are modified as “about” or “substantially,” it will be understood that these values and shapes should be construed as including a manufacturing or operational tolerance (e.g., ±10%) around the stated numerical values or shapes. It will also be understood that where elements, functions, etc. are described as being the same, they may also be substantially the same or similar even if the terminology substantially and similar are not used.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure is illustrated in a cross-sectional view, an electronic device may include a plurality of the device structures. The plurality of device structures may be arranged in an array and/or in a two-dimensional pattern.

Although the preferred example embodiments have been described above, it is not limited thereto, and can be implemented with various modifications within the scope of the claims, the detailed description of the invention, and the accompanying drawings.

What is claimed is:

1. A method of manufacturing a semiconductor package, comprising:
forming a coating layer including a surface-active material on a main pad of a package substrate;
applying a flux to a connecting solder pattern included on a semiconductor chip;
mounting the semiconductor chip on the package substrate so that the connection solder pattern and the main pad are in contact with each other;
forming a flux structure by combining the flux with the surface-active material of the coating layer; and
removing at least a portion of the coating layer and the flux structure.

2. The method of manufacturing a semiconductor package of claim 1, wherein:
the surface-active material includes a hydrophilic portion and a hydrophobic portion.

3. The method of manufacturing a semiconductor package of claim 2, wherein:
the flux structure includes
a core containing a flux material, and
the surface-active material connecting the core; and
the flux structure has a micelle structure such that the hydrophilic portion of the surface-active material constitutes a surface.

4. The method of manufacturing a semiconductor package of claim 1, wherein:
the coating layer further includes polyvinyl alcohol.

5. The method of manufacturing a semiconductor package of claim 4, wherein:
the coating layer includes 5 wt % to 50 wt % of the surface-active material and 50 wt % to 95 wt % of the polyvinyl alcohol by total weight of the coating layer.

6. The method of manufacturing a semiconductor package of claim 1, further comprising:
removing the at least a portion of the coating layer and the flux structure using water.

7. The method of manufacturing a semiconductor package of claim 1, wherein:
the flux structure surrounds at least a portion of a side surface of the connection solder pattern.

8. The method of manufacturing a semiconductor package of claim 1, further comprising:
covering an upper surface of the package substrate.

9. The method of manufacturing a semiconductor package of claim 8, wherein:
removing at least a portion of the coating layer and the flux structure includes completely removing the coating layer and the flux structure.

10. A method of manufacturing a semiconductor package, comprising:
forming a coating layer including a surface-active material including a hydrophilic portion and a hydrophobic portion on a main pad of a package substrate;
applying a flux including a hydrophobic material to a connecting solder pattern on a chip pad of a semiconductor chip,
mounting the semiconductor chip on the package substrate so that the connection solder pattern and the main pad penetrate the coating layer, wherein
the flux combines with the hydrophobic portion of the surface-active material to form a flux structure having a micelle structure; and
removing at least a portion of the coating layer and the flux structure.

11. The method of manufacturing a semiconductor package of claim 10, wherein:
a surface of the flux structure is composed of the hydrophilic portion of the surface-active material.

12. The method of manufacturing a semiconductor package of claim 10, wherein:
the flux structure surrounds at least a portion of a side surface of the connection solder pattern.

13. The method of manufacturing a semiconductor package of claim 10, wherein:
the coating layer further includes polyvinyl alcohol.

14. The method of manufacturing a semiconductor package of claim 13, wherein:
the coating layer includes 5 wt % to 50 wt % of the surface-active material and 50 wt % to 95 wt % of the polyvinyl alcohol by total weight of the coating layer.

15. A semiconductor package, comprising:
a package substrate including a main pad;
a semiconductor chip mounted on the package substrate and including a chip pad;
a connection bump located between the main pad and the chip pad; and
a flux structure located on a side surface of the connection bump, the flux structure having a micelle structure including a core of flux material and a surface-active material bonded to the core.

16. The semiconductor package of claim 15, wherein:
the surface-active material includes a hydrophilic portion and a hydrophobic portion, and
a surface of the flux structure is composed of the hydrophilic portion of the surface-active material.

17. The semiconductor package of claim 15, wherein the connection bump comprises:
a connection solder pattern located on the main pad, and
a connection pillar located on the connection solder pattern and connected to the chip pad.

18. The semiconductor package of claim 17, wherein:
the flux structure surrounds at least a portion of the connection solder pattern.

19. The semiconductor package of claim 18, wherein:
the flux surrounds at least a portion of the connection pillar.

20. The semiconductor package of claim 15, further comprising:
a coating layer covering at least a portion of an upper surface of the package substrate not overlapping the main pad.
